(19) United States
(12) Patent Application Publication
(10) Pub. No.: US 2007/0047609 A1
(43) Pub. Date: Mar. 1, 2007

(54) Wafer testing of edge emitting lasers

(76) Inventors: Daniel A. Francis, Oakland, CA (US); Ashish K. Verma, San Jose, CA (US)

Correspondence Address: WORKMAN NYDEGGER;(F/K/A WORKMAN NYDEGGER & SEELEY), 60 EAST SOUTH TEMPLE, 1000 EAGLE GATE TOWER, SALT LAKE CITY, UT, 84111, US

(21) Appl. No.: 11/215,208

(22) Filed: Aug. 30, 2005

(51) Int. Cl. H01S 5/00

(52) U.S. Cl. 372/50.21

(57) ABSTRACT

Methods and apparatuses for wafer testing edge emitting lasers and providing a vertical emission from an edge emitting laser. A plurality of edge emitting lasers can be formed on a semiconductor wafer. One or more grooves can be etched into the semiconductor wafer to form etched facets for the edge emitting lasers. A current can be applied to at least one edge emitting laser to produce at least one optical output. An evaluation of the at least one optical output can be performed while the edge emitting lasers are still in wafer form. Edge emitting lasers may also be produced including a reflective surface for reflecting at least one edge emitted optical signal in a vertical perpendicular direction. The reflective surface can be created using an etching process during manufacture of the edge emitting laser.

### CROSS-REFERENCE TO RELATED APPLICATIONS

Not applicable.

### BACKGROUND OF THE INVENTION

1. The Field of the Invention

The present invention relates generally to edge emitting lasers. More particularly, the present invention relates to systems and methods for testing edge emitting lasers at the wafer level and for producing edge emitting laser with a vertical reflected emission.

2. The Relevant Technology

Communication networks employing fiber optic technology are known as optical communication networks. Optical communication networks are typically characterized by high bandwidth and reliable, high-speed data transmission. As a result, fiber optic technology is increasingly employed in the transmission of data over communications networks.

Optical communication systems utilize optoelectronic devices as sources of light for sending data signals. One type of optoelectronic device implemented in optical communication systems are edge emitting semiconductor lasers. Edge emitting lasers typically have a laser cavity in the plane of the semiconductor device, and emit light out through a cleaved edge in an elliptical output pattern. Examples of edge emitting lasers include double heterostructure (“DH”), quantum well (“QW”), strained layer (“SL”), distributed feedback (“DFB”), and distributed Bragg reflector (“DBR”) lasers.

In some edge emitting lasers, the laser's cleaved facets provide feedback during the generation of optical signals. For Example, a typical strip contact Fabry-Perot laser diode can include a bottom contact, cladding layers, an active layer, another cladding layer, lateral confinement layers surrounding a stripe contact, as is known to one of ordinary skill in the art. The strip type contact receives an injection current and an optical output beam is emitted from the active region through etched facets.

Other edge emitting lasers, such as DFB and DBR lasers, use distributed reflection from a grating. In DFB and DBR lasers, The optical feedback is obtained by the periodic variation of the effective refractive index of the grating located inside or near the laser cavity. A DFB laser, for example, places a corrugation (e.g., a grating) directly on the active region or its cladding. A DBR laser, on the other hand, places the corrugation (e.g., a grating) in a passive waveguide coupled to the active waveguide. One benefit of the DFB and DBR lasers is that the choice of grating can define the wavelength and can be used to fabricate single-mode lasers.

Edge emitting lasers often include some form of a waveguide and several different types of waveguides exist. For example, there are stripe waveguides, ridge waveguides, and buried heterostructure waveguides. Stripe lasers, ridge waveguide lasers, and buried heterostructure lasers can be fabricated with a grating to produce DFB and DBR lasers. However, DFB lasers will often be based on buried heterostructures because they show better lateral single-mode and threshold behavior.

With reference to FIGS. 1A and 1B, a conventional DFB laser fabrication process includes forming a grating 102 on a wafer 100. The grating 102 is oriented parallel to cleavage planes 104. This allows a longitudinal mode in a die to interact with the grating 102. Waveguides 106, which can be, for example, stripe waveguides, ridge waveguides, or buried heterostructure waveguides, are formed perpendicular to the gratings 102.

The wafer 100 is cleaved and, referring to FIG. 1B, cleaved laser bars 104 can have an antireflection (“AR”) coating formed on cleaved facets 112. A second facet 114 can also have an AR coating or the second facet 114 can have a high reflectivity (“HR”) coating formed thereon depending on the type of laser. A saw region 116 is shown between waveguides 106. The saw region 116 is a region in between the waveguides 106 where the lasers will be cut to produce individual lasers from the wafer 100.

In some DFB lasers, such as phase-shifted DFB lasers, it is desirable to use an AR coating to reduce the facet reflection to less than about 1% so as to suppress the Fabry-Perot modes. AR coatings that can be used include single layer coatings and multi-layer coatings.

Single layer AR coatings commonly have a coating that is an odd number of quarter-wavelengths thick and have a refractive index close to the square root of the average refractive index of the laser. The reflectance response of a single layer AR coating is a function of wavelength. The bandwidth of a single layer ultra-low reflectivity AR coating is comparatively narrow, which can make it difficult to achieve a low reflectivity at the lasing wavelength. Consequently, single layer AR coatings used for DFB lasers commonly have a reflectivity of about 1% or higher.

Alternatively, a multi-layer AR coating can be used, such as multilayer coatings having quarter wavelength and half wavelength thick layers with the refractive index of each layer selected to produce a desired reflectance response. An advantage of a multi-layer AR coating is that the bandwidth of an ultra-low reflectivity multi-layer AR coating can be broader than a single layer ultra-low reflectivity AR coating. However, a multilayer AR coating typically requires a greater number of layers to produce a low reflectivity, increasing its cost.

One drawback with conventional edge emitting laser fabrication processes is that additional processes (e.g., cleaving, polishing, and coating the facets) must be performed before the lasers can be initially tested. Performing these processes prior to determining whether the laser is functional is not cost effective because some of the lasers often will not be functional. In other words, the functionality of edge emitting lasers is often not known until these expensive additional processing steps are completed. A more cost-effective approach would be to abandon the edge emitting laser prior to conducting the additional manufacturing, setup, and/or packaging processes. Unfortunately, many of these steps need to be performed because edge emitting lasers cannot be tested in wafer form.

The ability to test lasers at the wafer level has been described as one benefit for production of certain surface emitting lasers, such as vertical cavity surface emitting lasers (“VCSEL”). For example, VCSEL laser diodes may be tested at the wafer level by positioning the wafer under a test microscope where a probe delivers a drive current to the VCSEL. The emitted light is collected via a core optical fiber attached to the microscope so that a series of spectra can be taken. This method allows for testing of the VCSELs for various operational characteristics. If the VCSEL falls outside of the specified ranges it can be marked, or designated in some fashion, so as to be discarded. This allows for only known good VCSELs to be identified for subsequent packaging and additional manufacturing steps.

However, testing of edge emitting lasers, such as DFB lasers, at the wafer level, or while the DFB lasers are still in wafer form has not been achieved. Currently, additional manufacturing processes have to be conducted before the first test/qualification. Thus, one aspect of the present invention are methods and apparatuses for testing edge emitting lasers, such as DFB lasers, at the wafer level.

Another benefit of VCSELs are their surface-normal emission and nearly identical to the photo detector geometry, which provides easier alignment and packaging of the VCSEL in many instances. Referring to FIG. 1C, an edge emitting laser 120 is depicted in an example optical signal transmission assembly 125. As shown, the typical edge emitting laser 120 emits light horizontally from each edge facet. A first emission 122 is received by an optical fiber 130 and a second optical emission 124 is received by a photodiode that monitors the optical emission characteristics of the edge emitting laser 120.

Because of the lateral emission direction of the edge emitting laser, conventional edge emitting lasers may be limited in their ability to be implemented in many optical signal transmission assemblies and packaging arrangements. Therefore, another aspect of the present invention relates to edge emitting lasers including at least one integral reflective surface for redirecting an optical emission in a substantially vertical direction.

### BRIEF SUMMARY OF THE INVENTION

Systems and methods for testing edge emitting lasers at the wafer level are disclosed. A method can include forming edge emitting lasers on a semiconductor wafer, etching one or more grooves into the semiconductor wafer to form etched facets for the edge emitting lasers, applying a current to at least one of the edge emitting lasers to produce an optical output from the at least one edge emitting laser, and performing an evaluation of the optical output for the at least one edge emitting laser while the edge emitting lasers are still in the wafer form.

Semiconductor wafers are described. A semiconductor wafer can include a plurality of edge emitting lasers formed on a substrate. The plurality of edge emitting layers can include a top cladding layer, one or more grooves etched into the top cladding layer and extending through an active region of the plurality of edge emitting lasers. The one or more grooves can form one or more etched facets for the plurality of edge emitting lasers. The one or more etched facets can be configured to allow transmission of an optical signal from the active regions the plurality of edge emitting lasers while still in wafer form.

Methods for manufacturing edge emitting lasers such that the edge emitting lasers are tested while still in wafer form are disclosed. A method can include providing a semiconductor wafer having edge emitting lasers grown thereon, forming a plurality of grooves in the semiconductor wafer, wherein the plurality of grooves form facets for the edge emitting lasers, applying a current to at least one of the edge emitting lasers such that the at least one edge emitting laser emits laser light, wherein the laser light is reflected by surfaces of the plurality of grooves toward a testing apparatus, evaluating the laser light emitted from the at least one edge emitting laser to determine whether the at least one edge emitting laser passes an evaluation, and selectively discarding or performing additional manufacturing steps on the at least one edge emitting laser based on a result of the evaluation.

Edge emitting lasers are described. An edge emitting laser can include a first contact a second contact, a first cladding layer above the first contact, a second cladding layer below the second contact, an active layer between the first cladding layer and the second cladding layer, and a reflective surface. The reflective surface can be produced using an etching process during manufacture of the edge emitting laser.

These and other advantages and features of the present invention will become more fully apparent from the following description and appended claims, or may be learned by the practice of the invention as set forth hereinafter.

### BRIEF DESCRIPTION OF THE DRAWINGS

To further clarify the above and other advantages and features of the present invention, a more particular description of the invention will be rendered by reference to specific embodiments thereof which are illustrated in the appended drawings. It is appreciated that these drawings depict only typical embodiments of the invention and are therefore not to be considered limiting of its scope. The invention will be described and explained with additional specificity and detail through the use of the accompanying drawings in which:

FIG. 1A illustrates initial processes in a conventional DFB laser fabrication process;

FIG. 1B illustrates additional processes in the conventional DFB laser fabrication process;

FIG. 1C illustrates a conventional packaging and setup of an edge emitting laser.

FIG. 2A illustrates a side cross-sectional view of a silicon wafer including a plurality of edge emitting lasers according to an example embodiment of the present invention;

FIG. 2B illustrates a top perspective view of a silicon wafer including a plurality of edge emitting lasers according to an example embodiment of the present invention;

FIG. 3 depicts a partial cross sectional illustration of an edge emitting laser being tested at the wafer level according to an example embodiment of the present invention;

FIG. 4 depicts an illustration of a wafer including several edge emitting lasers formed thereon where a number of waveguides are offset from perpendicular in relation to etched facets according to example embodiments of the present invention;

FIG. 5 depicts a side cross-sectional illustration of a wafer including several edge emitting lasers formed thereon where a number of etched grooves are offset from vertical in relation to a waveguide according to example embodiments of the present invention;

FIG. 6 depicts a block diagram illustrating a method for testing an edge emitting laser at the wafer level according to an example embodiment of the present invention;

FIG. 7 illustrates a method for receiving an optical emission from an edge emitting laser at the wafer level according to an example embodiment of the present invention;

FIG. 8 illustrates a method for receiving an optical emission from an edge emitting laser at the wafer level according to an example embodiment of the present invention;

FIG. 9 illustrates a method for receiving an optical emission from two edge emitting lasers at the wafer level according to an example embodiment of the present invention; and

FIG. 10 illustrates a method for receiving an optical emission from an edge emitting laser at the wafer level according to an example embodiment of the present invention.

FIG. 11A illustrates a partial cross-sectional view of an edge emitting laser in the wafer form according to an example embodiment of the present invention.

FIG. 11B illustrates an edge emitting laser according to an example embodiment of the present invention.

FIG. 12A illustrates a partial cross-sectional view of an edge emitting laser in the wafer form according to an example embodiment of the present invention.

FIG. 12B illustrates an edge emitting laser according to an example embodiment of the present invention.

FIG. 13A illustrates a partial cross-sectional view of an edge emitting laser in the wafer form according to an example embodiment of the present invention.

FIG. 13B illustrates an edge emitting laser according to an example embodiment of the present invention.

FIG. 14 illustrates how the integral reflective surface can change the packaging arrangement and setup of the edge emitting laser.

FIG. 15A is a cross-sectional illustration of an edge emitting laser while the edge emitting laser is at the wafer level.

FIG. 15B illustrates an edge emitting laser produced from the partial cross section view of the wafer depicted in FIG. 15A according to an example embodiment of the present invention.

FIG. 16A is a cross-sectional illustration of an edge emitting laser while the edge emitting laser is at the wafer level.

FIG. 16B illustrates an edge emitting laser produced from the partial cross section view of the wafer depicted in FIG. 15A according to an example embodiment of the present invention.

FIG. 17 illustrates how integral reflective surfaces can change the packaging arrangement and setup of an edge emitting laser.

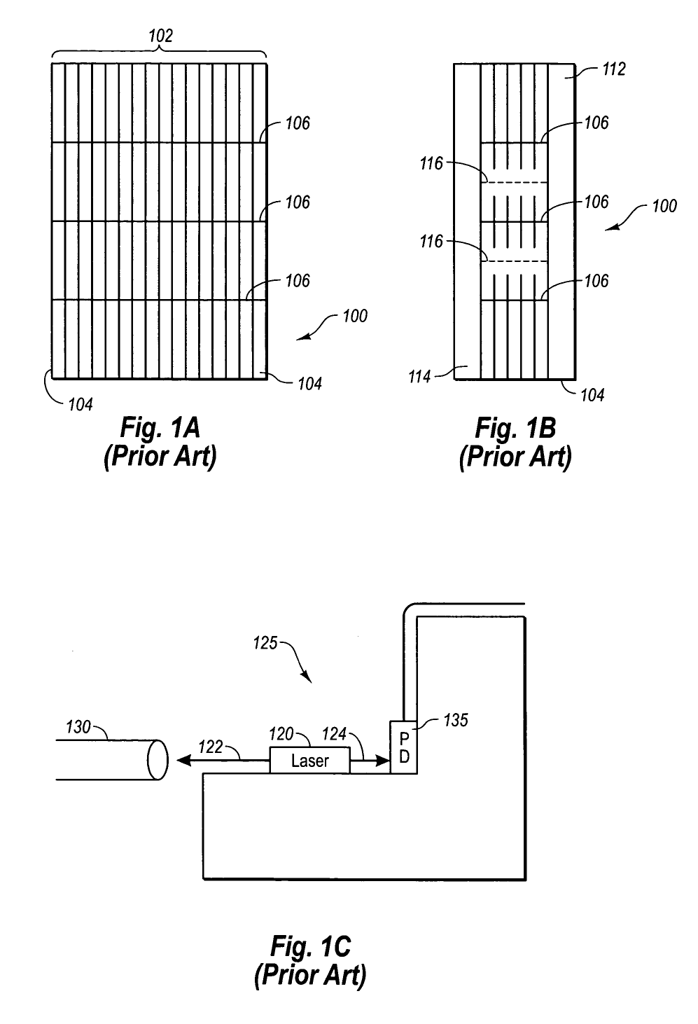

### DETAILED DESCRIPTION OF THE PREFERRED EMBODIMENTS

Embodiments of the present invention relate to testing edge emitter lasers at the wafer level. Embodiments of the present invention are described in the context of particular types of lasers and configurations, but one of ordinary skill in the art can appreciate that embodiments of the invention can be applied to any type of edge emitting laser. The principles of the present invention are also described with reference to the attached drawings to illustrate the structure and operation of example embodiments used to implement the present invention. Using the diagrams and description in this manner to present the invention should not be construed as limiting its scope. Additional features and advantages of the invention will in part be obvious from the description, including the claims, or may be learned by the practice of the invention.

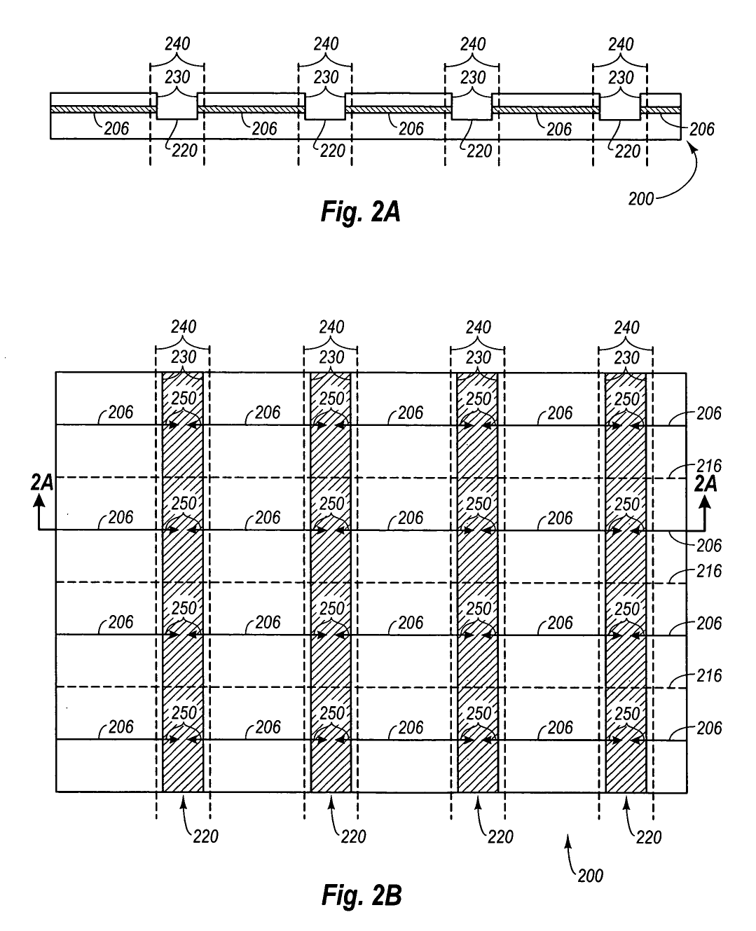

FIGS. 2A and 2B illustrate an example wafer 200 including a plurality of edge emitting lasers each having an active region 206. In this example, the wafer 200 illustrated in FIGS. 2A and 2B includes several grooves 220 that have been etched into the wafer 200. The etched grooves 220 create etched facets 230 across the ends of the active regions 206 allowing for transmission of an optical signal 250 from the active regions 206 upon application of a test current to a particular edge emitting laser's active region 206. The etched grooves 220 create etched facets 230 back from where a cleaved facet will later be produced in a subsequent manufacturing step. The location of the cleaved facets is indicated in FIGS. 2A and 2B by dotted lines 240. In other words, the wafer 200 is likely to be cleaved at the locations represented by the dotted lines 240. Alternatively, the etched facets may be satisfactory in some instances and cleaving or other process can occur within each particular groove to separate the lasers.

Upon application of a test current to a particular laser, the active region 206 of a particular laser emits an optical signal 250 that is transmitted into at least one of the etched grooves 220. The groove etched into the wafer enables the emitted optical signal to be detected while the edge emitting lasers are still in wafer form. The optical signal is received and evaluated in order to determine whether the corresponding edge emitting laser conforms to applicable qualification standards. In the instance that the optical emission received from an active region 206 qualifies under the applicable standards, additional manufacturing processes (e.g., cleaving, polishing, coating, and packaging) are conducted to produce a corresponding edge emitting laser. In the instance that the emission from the particular active region 206 does not conform to applicable standards, the corresponding laser can be marked and disposed of prior to additional manufacturing steps. In other words, any number of the additional manufacturing processes (e.g., cleaving, polishing, coating, etc.) may not be performed for non-conforming lasers that are identified as non-conforming at the waver level.

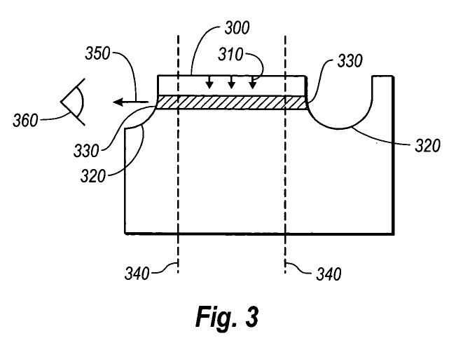

The wafer shown in FIG. 3 can be any type of wafer configured to produce any type of edge emitting laser (e.g., DH, QW, SL, DFB, and DBR lasers). The edge emitting lasers may have any type of waveguide (e.g., stripe waveguides, ridge waveguides, and buried heterostructure waveguides). The wafer 200 can be any shape, such as round or square, and the edge emitting lasers can be produced on the wafer in any arrangement.

Referring now to FIG. 3, a partial cross sectional illustration of a portion of a wafer including an edge emitting laser 300 being tested at the wafer level is shown. Grooves 320 are etched along the respective ends of the edge emitting laser 300. The grooves 320 define etched facets 330 of the edge emitting laser 300. In this example, the two grooves 320 are etched at a location back from where the wafer will be cleaved to create cleared facets, the location of which is as shown at lines 340. A current 310 is then applied to the edge emitting laser 300 inducing an optical emission 350 to be emitted from an active region 332 of the edge emitting laser 300.

The emission 350 may be emitted and received from either end of the edge emitting laser 300 depending on the type of edge emitting laser and coatings that may be applied to the etched facets 330. Coatings may not be applied at this stage for various reasons including cost, but embodiments of the invention include coating the etched facets 330 of the laser 300 in wafer form. The emission 350 is received and evaluated by a test apparatus 360. The edge emitting laser 300 can be marked for later disposal where the edge emitting laser 300 does not meet qualification standards. On the other hand, where the evaluation of the edge emitting laser 300 indicates that the edge emitting laser 300 meets qualification standards, the edge emitting laser 300 can be marked (or left unmarked) for further processing that may include, but is not limited to, cleaving, polishing, coating, and/or packaging. The edge emitting laser 300 can be any type of edge emitting laser and can include additional components (e.g., a waveguide and corrugations).

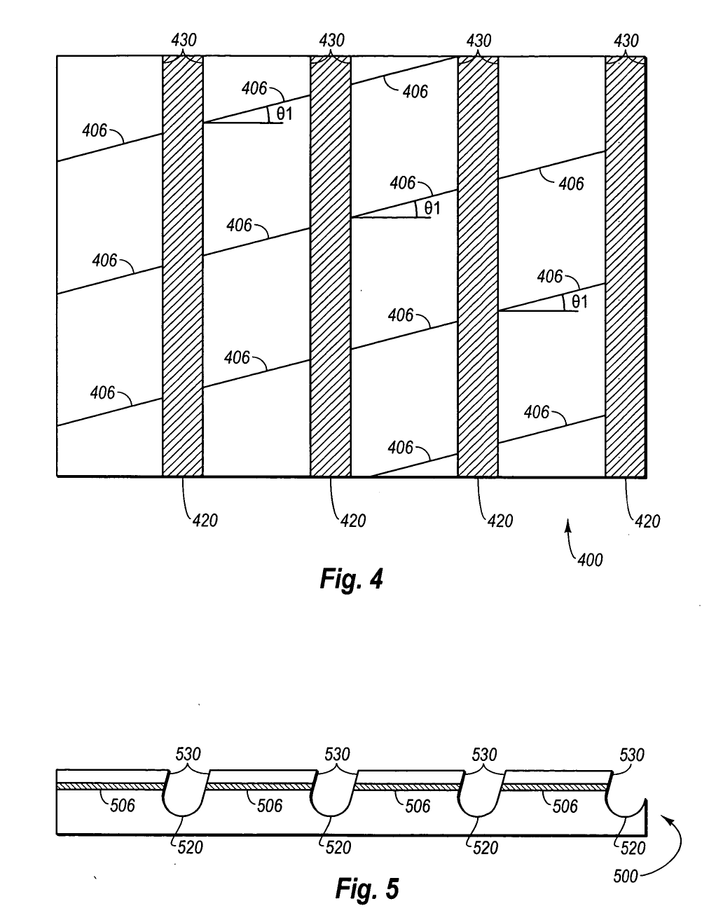

According to an aspect of the present invention, a reduction in reflectivity may be achieved by angling a waveguide. Angling a waveguide results in angled facets and a reduction in reflectivity at the facets. Referring now to FIG. 4, a top view illustration of a wafer is shown where a plurality of waveguides 406 are offset an angle θ₁ in relation to the etched channels or grooves 420. The result of this offset of the waveguides 406 from perpendicular to the grooves 420 is that the reflectivity responses of the facets 430 are decreased. A tilt angle θ₁ of even a few degrees may be sufficient. Reducing reflectivity of the facets 430 can be used in conjunction with, or independent of, AR coatings for similar reasons that AR coatings are currently used to reduce reflection at the facets.

Similarly, the process of etching the grooves can be controlled such that they are not entirely vertical to reduce reflectivity in applications where reflectivity response at the facets is not desirable. Non-vertical etched grooves result in etched facets that are also not entirely vertical. The effect of placing the etch or etching the grooves at an angle from vertical is that additional reduction in reflectivity may be achieved. Referring now to FIG. 5, a cross-sectional illustration of a wafer 500 is shown where a plurality of etched grooves 520 are offset an angle θ₂ from vertical. The result of this angling of the etched channels 520 from vertical is that the reflectivity responses of the etched facets 530 are further decreased. A tilt angle θ₂ of even a few degrees may be sufficient.

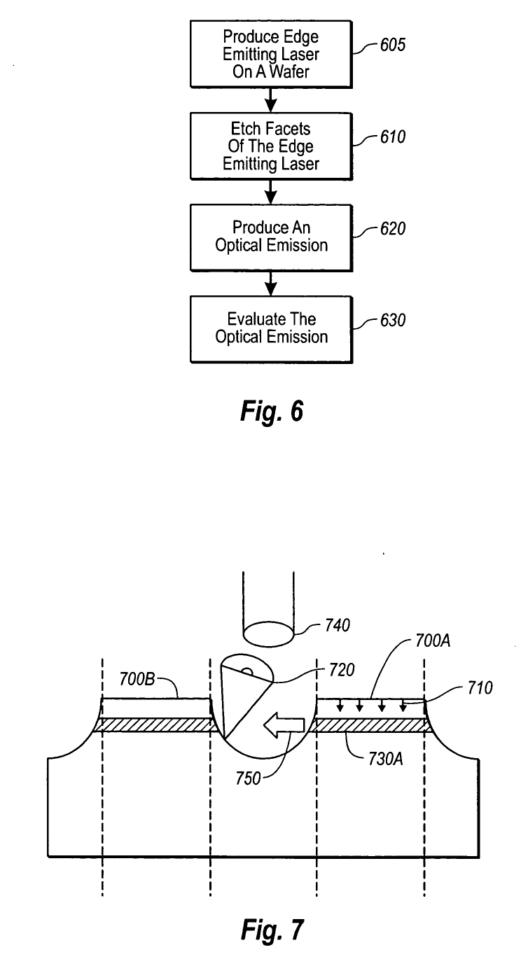

Referring now to FIG. 6, a block diagram illustrating a method for testing an edge emitting laser at the wafer level is shown according to an example embodiment of the present invention. As illustrated, and discussed in further detail above, an edge emitting laser is produced on a silicon wafer using methods of epitaxial growth known to one of ordinary skill in the art (600) or using another growth method known to one of skill in the art. The edge emitting laser can be any type of laser and typically includes layers that include, but are not limited to, cladding layers, an active layer, a guide layer, and a reflective layer situated between upper and lower electrodes or contacts. A cladding layer or other layer may include configurations or gratings that have a predetermined period as described above.

One of ordinary skill will appreciate that many edge emitting lasers can be produced on a single silicon wafer in any arrangement or configuration as is known or advantageous in the production of edge emitting lasers. Moreover, the methods of the present invention can also be implemented to test and qualify a plurality of edge emitting lasers at the wafer level simultaneously, or in any successive order.

After the edge emitting lasers are produced, grown, or formed on the silicon wafer, grooves, or other types of canals or cavities, are etched into the wafer along at least one side of the edge emitting lasers (610). The etched grooves can define the facets of the edge emitting lasers while the edge emitting lasers are still in wafer form. Because the lasers may be cleaved at a later stage of the fabrication process, the etched facets may be temporary for testing purposes. In another example, however, the etched grooves may correspond with the cleavage planes of the wafer. In this case, the layers that were not etched are cleaved.

An AR (or HR) coating can be applied to the etched facets to reduce (or increase) reflectivity from the facets depending on the circumstances. Single layer or multilayer AR coatings can be used. Examples of single layer AR coatings that may be used include Al₂O₃, SiO, and HfO₂, as well as other suitable coatings having a suitable attributes for the particular application. However the type of laser may allow for a single AR coating applied to the entire wafer, and in some instances where quarter wave shifted DFB lasers are being tested an AR coating may not need to be applied to the facets at all. The etched facets of the present invention may be particularly advantageous in conjunction with quarter wave shifted DFB lasers because these devices do not have trouble associated with power at the facets known as catastrophic optical damage (“COD”). Where appropriate, facet coatings can be applied to the facets respectively and can be AR (or HR) coatings designed to allow light to be emitted from an etched facet.

While the edge emitting lasers are still in wafer form, a current is applied to at least one edge emitting laser producing an optical emission (620). The current may be applied by a testing probe. The current induces the optical emission in the edge emitting laser, which is emitted from at least one of the laser's etched facets. The emission can be laterally guided by an optical guiding mechanism such as an optical waveguide. The emission is received by the testing probe and is evaluated in order to determine whether the edge emitting laser meets certain operational standards (630). If the edge emitting laser does not meet such operational standards it can be marked (e.g., using an inking process) for later disposal prior to conducting additional manufacturing steps. If the edge emitting laser qualifies under the requirements of the evaluation, the edge emitting laser can be forwarded for additional manufacturing steps, such as for example, cleaving, polishing, coating, and packaging.

Referring to FIG. 7, a method and apparatus for evaluating an optical emission 750 transmitted from an edge emitting laser 700A at the wafer level is shown according to an example embodiment of the present invention. A test current 710 is applied to the edge emitting laser 700A causing an optical emission 750 from an active layer 730A of the edge emitting laser 700A. The optical emission 750 scatters off of an adjacent edge emitting laser 700B as light 720. The edge emitting laser 700B from which the light 720 scatters from is located next to the edge emitting laser under test 700A.

An optical test apparatus 740 (e.g., an optical collection microscope) receives the scattered optical light 720 and an evaluation of the scattered light 720 is conducted to determine whether the edge emitting laser 700A meets qualification standards. The test apparatus 740 may be calibrated to evaluate any characteristics of the scattered optical emission 720 (e.g., the power of the scattered optical emission 720 and the wavelength characteristics of the scattered optical emission 720). The testing of the edge emitting laser 700A may be done at various temperatures that may be beneficial for qualification of the edge emitting laser 700A. In some instances it may be necessary for only certain edge emitting lasers to be tested at one time in order to insure that the edge emitting lasers do not interfere with the testing of other nearby edge emitting lasers. Further, the test apparatus 740 can be calibrated to account for changes due to the effects of the scattering of the optical emission 710 as it scatters and becomes the light 720 that is reflected from the facet of the laser 700B, or from a surface of the groove that has been previously etched.

Various other means and apparatus can be used to receive the optical emission during testing of an edge emitting laser at the wafer level. Different manufacturing processes may also be implemented in order to create the grooves and facets required for producing the optical emission in the edge emitting laser. For example, different etching processes may be implemented to provide a reflective surface allowing redirection of the optical emission toward the optical testing apparatus.

The etching process may include isotropic or anisotropic etching processes. An anisotropic etch is selective to certain crystal planes and may be chosen for its tendency to etch certain planes faster than other planes to form a reflective surface. Generally, acid based etches (e.g., sulfuric acid, phosphoric acid, water etching and hydrogen peroxide etching) tend to be anisotropic. Conversely, bromine based etching tends to be isotropic in that it is not selective to certain crystalline planes.

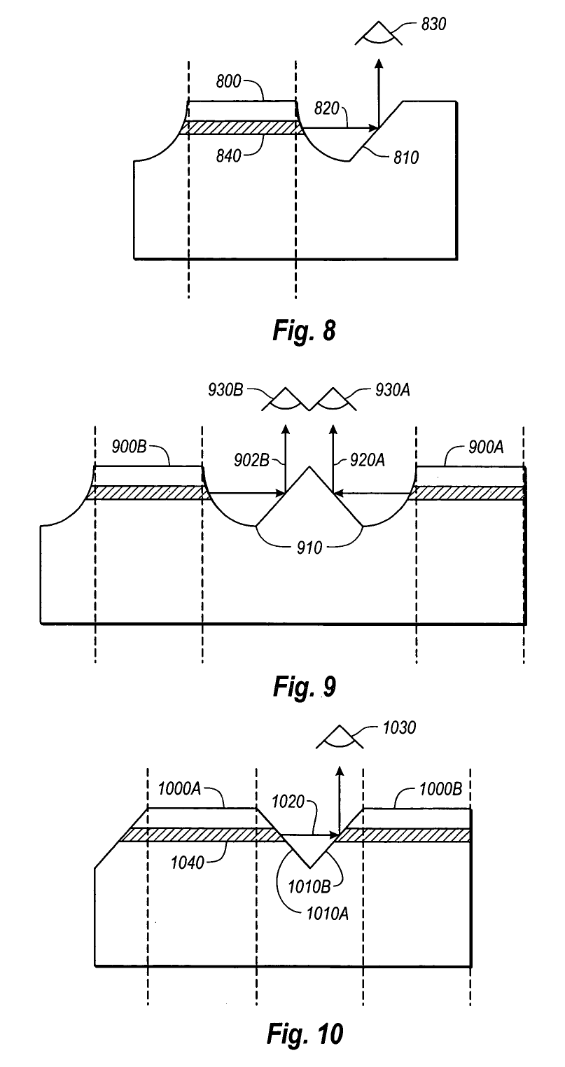

Referring to FIG. 8, an illustration of an edge emitting laser 800 being tested at the wafer level is shown according to an example embodiment of the present invention. As shown in FIG. 8, a reflective surface 810 has been produced (e.g., by a manufacturing process such as an anisotropic etching process). An optical signal 820 is emitted from an active region 840 of an edge emitting laser 800. The reflective surface 810 is produced so as to reflect the optical signal 820 toward an optical testing apparatus 830. The optical testing apparatus 830 may be any optical testing apparatus that is capable of receiving the optical signal 820 and analyzing a characteristic of the optical signal 820 (e.g., spectrum or power). The optical testing apparatus 830 can also include executable logic for comparing a result of the analysis to predetermined threshold qualification values (e.g., industry requirements) in order to qualify the edge emitting laser 800 for additional manufacturing steps and packaging. The optical testing apparatus 830 can also be connected to other devices such as a data processing machine for carrying out such comparison and can include a display or other means for presenting a result of the analysis to a user.

A reflective surface for redirecting an optical emission from an edge emitting laser under test at the wafer level can take different shapes and configurations. For example, turning to FIG. 9, two edge emitting lasers 900A and 900B are shown being tested at the wafer level. A triangular-shaped reflective surface 910 has been produced for reflecting both optical signals 920A and 920B from the two edge emitting lasers 900A and 900B toward evaluation devices 930A and 930B for receiving, evaluating, and qualifying the optical signals 920A and 920B. The evaluation devices 930A and 930B may be distinct devices or combined into a single testing apparatus.

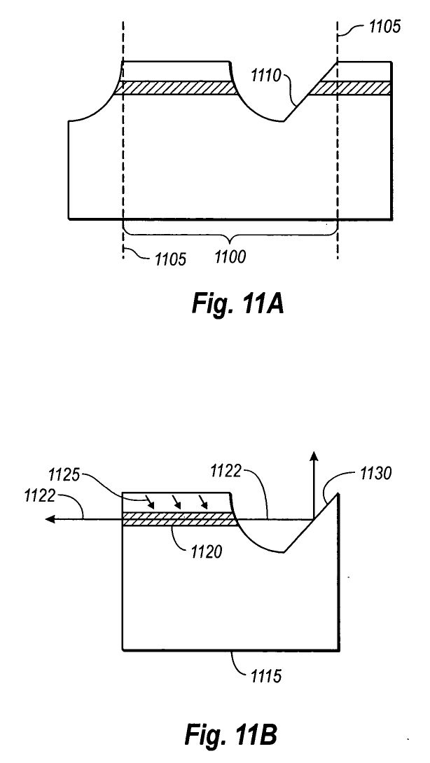

Different aspects of the present invention can also be accomplished in various embodiments. For example, referring to FIG. 10, an illustration of an edge emitting laser 1000A being tested at the wafer level is shown according to an example embodiment of the present invention. Reflective surfaces 1010A and 1010B have been produced (e.g., by a manufacturing process such as an anisotropic etching process). An optical signal 1020 is emitted from an active region 1040 of edge emitting laser 1000A. The reflective surfaces 1010A and 1010B can be produced so as to reflect the optical signal 1020 toward an optical testing apparatus 1030. The optical testing apparatus 1030 conducts an analysis of the reflected optical emission 1020 to determine whether the edge emitting laser 1000A qualifies for further processing or should be discarded. An additional benefit of the embodiment shown in FIG. 10 is that the reflective surfaces 1010A and 1010B represent angled facets for edge emitting lasers 1000A and 1000B and can include the antireflective aspects similar to that described above with reference to FIGS. 4 and 5.

In many instances, at least one reflective surface used to test an edge emitting laser while the edge emitting laser was at the wafer level can also be retained in the laser to form a reflective surface for redirecting the optical emission in a desired direction. In this manner, the same manufacturing process, such as an anisotropic etching process, can be used to make an edge emitting laser with an integral reflective surface.

Referring to FIG. 11A, a partial cross-sectional view of an edge emitting laser 1100 in the wafer form is shown according to an example embodiment of the present invention. The edge emitting laser 1100 is substantially similar to that depicted in FIG. 8 as shown. However, as illustrated in FIG. 11A, the location where cleaved facets will later be produced as shown by dotted lines 1105 has been located such that a reflective surface 1110 that has been produced (e.g., by a manufacturing process such as an anisotropic etching process) will be retained when the edge emitting laser is produced as a final product. The reflective surface 1110 can be produced at the wafer level for the purpose of testing the laser 1100 at the wafer level and/or for the purpose of reflecting an optical emission from the edge emitting laser 1100 in a substantially perpendicular direction after the laser is no longer at the wafer level.

Referring to FIG. 11B, an edge emitting laser 1115 produced from the partial cross section view of the wafer depicted in FIG. 11A is shown according to an example embodiment of the present invention. As shown in FIG. 11B, the edge emitting laser 1115 includes an active region 1120 from which optical emissions 1122 are transmitted upon application of a current 1125. The edge emitting laser 1115 illustrated in FIG. 11B includes a reflective surface 1130 for reflecting one of the optical emissions 1122 emitted from the active region 1120 in a substantially perpendicular direction. In this manner the reflective surface may allow for different packaging and setup for the edge emitting laser 1115 than that that was previously available for conventional edge emitting lasers.

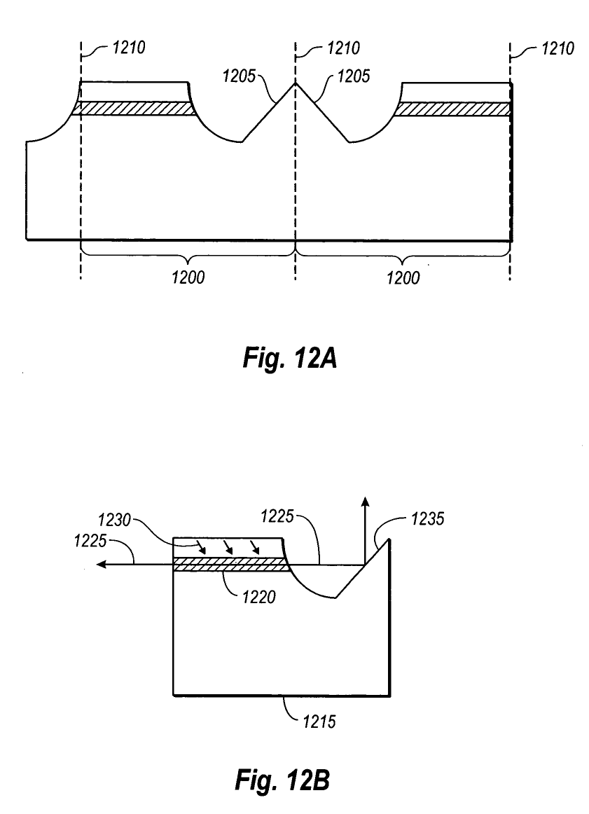

Referring to FIG. 12A, a partial cross-sectional view of two edge emitting lasers 1200 in the wafer form is shown according to an example embodiment of the present invention. The edge emitting lasers 1200 are substantially similar to that depicted in FIG. 9 at this point as shown in FIG. 12A. However, the location where cleaved facets will later be produced as indicated by dashed lines 1210 has been located such that reflective surfaces 1205 that were produced (e.g., by a manufacturing process such as an anisotropic etching process) will be retained in the edge emitting lasers that are produced as final products. As described above, the reflective surfaces 1205 can be produced at the wafer level for the purpose of testing the lasers 1200 at the wafer level and/or for the purpose of reflecting an optical emission from the edge emitting lasers 1200 in a substantially perpendicular direction.

Referring to FIG. 12B, an edge emitting laser 1215 produced from the partial cross section view of the wafer depicted in FIG. 12A is shown according to an example embodiment of the present invention. As shown in FIG. 12B, the edge emitting laser 1215 includes an active region 1220 from which optical emissions 1225 are transmitted upon application of a sufficient current 1230. The edge emitting laser 1215 illustrated in FIG. 12B includes a reflective surface 1235 for reflecting one of the optical emissions 1225 emitted from the active region 1220 in a substantially perpendicular direction. In this manner the reflective surface may allow for different packaging and setup for the edge emitting laser 1215 than that that was previously available for conventional edge emitting lasers.

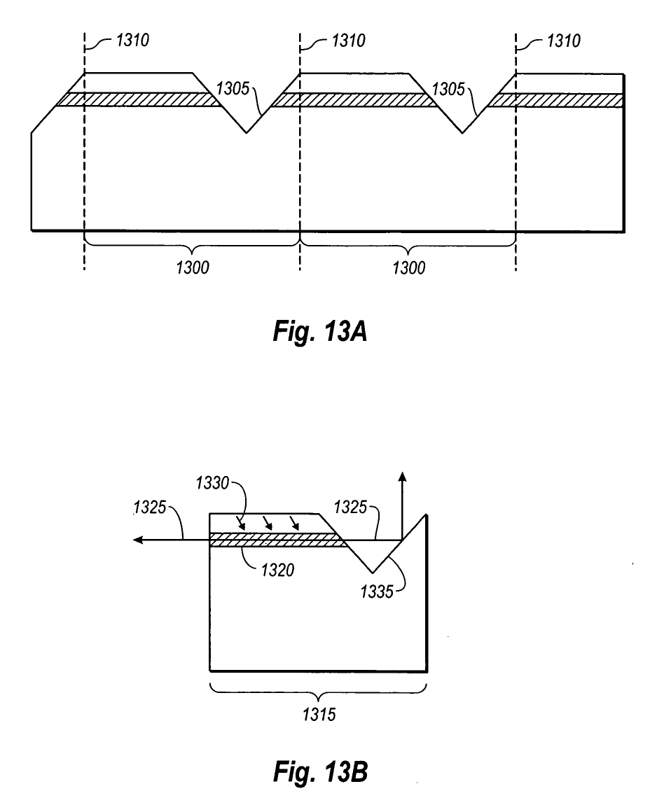

Referring to FIG. 13A, a partial cross-sectional view of two edge emitting lasers 1300 in the wafer form is shown according to an example embodiment of the present invention. The edge emitting lasers 1300 are substantially similar to that depicted in FIG. 10 at this point as shown in FIG. 13A. However, the location where cleaved facets will later be produced has been located as shown by dotted lines 1310 such that reflective surfaces 1305 that were produced (e.g., by a manufacturing process such as an anisotropic etching process) will be retained in the edge emitting lasers that are produced as a final product. As described above, the reflective surfaces 1305 can be produced at the wafer level for the purpose of testing the lasers 1300 at the wafer level and/or for the purpose of reflecting an optical emission from the edge emitting lasers 1300 that are later produced in a substantially perpendicular direction in the edge emitting.

Referring to FIG. 13B, an edge emitting laser 1315 produced from the partial cross section view of the wafer depicted in FIG. 13A is shown according to an example embodiment of the present invention. As shown in FIG. 13B, the edge emitting laser 1315 includes an active region 1320 from which optical emissions 1325 are transmitted upon application of a sufficient current 1330. The edge emitting laser 1335 includes a reflective surface 1335 for reflecting one of the optical emissions 1325 emitted from the active region 1320 in a substantially perpendicular direction. In this manner, the reflective surface 1335 may allow for different packaging and setup for the edge emitting laser 1315 than that that was previously available for conventional edge emitting lasers.

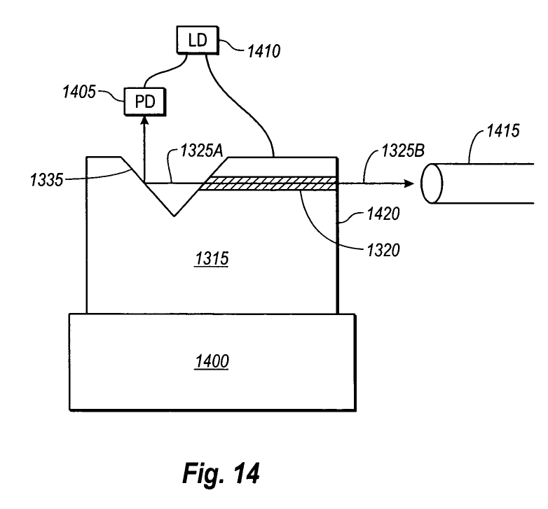

Referring to FIG. 14, an illustration depicting how the integral reflective surface 1335 can change the packaging arrangement and setup of the edge emitting laser 1315. The laser 1315 can be located upon a header 1400 or other appropriate means for supporting the laser in a particular position and alignment. As shown, the edge emitting laser 1315 emits two optical signals 1325A and 1325B from each end of the active region upon application of a sufficient current. A first optical emission 1325A is reflected from the integral reflective surface 1335 and is received by a photodiode 1405. The photodiode 1405 can serve any purpose, for example, the photodiode 1405 can monitor the output of the edge emitting laser 1400 and provide feedback to a laser driver 1410 that provides a drive current to the edge emitting laser 1400. A second optical emission 1325B is produced from the active region 1320 of the edge emitting laser 1315 and is received by an optical fiber 1415. In this manner, the photodetector 1405 can be located above the edge emitting laser 1315 to receive reflected optical signal 1325A and the optical fiber 1415 can be located along side of a facet 1420 of the edge emitting laser 1315 for receiving the second optical emission 1325B in a direction substantially perpendicular to the direction at which the photodiode 1405 receives the first optical emission 1325A.

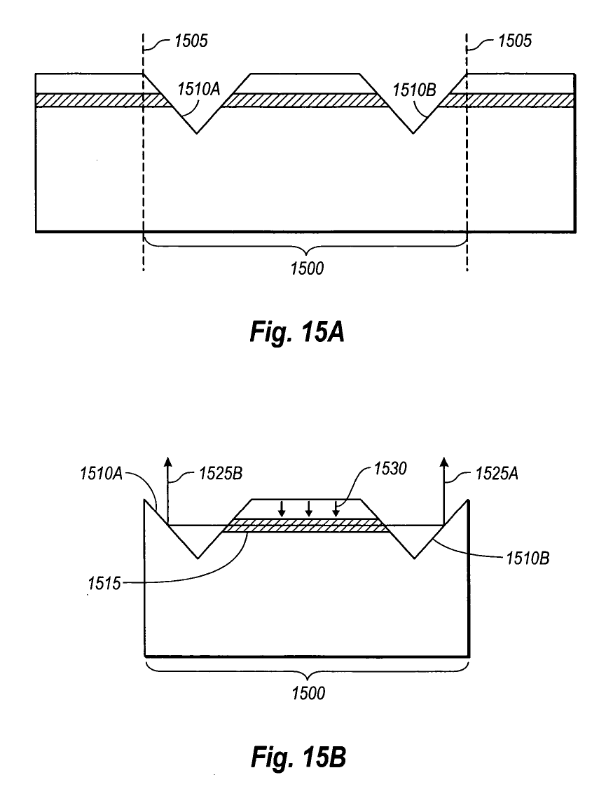

More than one reflective surface can be produced to reflect the optical emissions from an edge emitting laser. Each reflective surface can be produced to reflect the optical emissions in a preferred direction to be received for a desired purpose. Referring to FIG. 15A a cross-sectional illustration of an edge emitting laser 1500 is illustrated while the edge emitting laser 1500 is at the wafer level. The edge emitting laser 1500 is substantially similar to that depicted in FIG. 10 at this point as shown in FIG. 15A. However, as illustrated in FIG. 15A, the location where cleaved facets will later be produced has been located as shown by dotted lines 1505 such that two reflective surfaces 1510 that were produced (e.g., by a manufacturing process such as an anisotropic etching process) will be retained when the edge emitting laser 1500 is produced as a final product. As described above, the reflective surfaces 1510 can be produced at the wafer level for the purpose of testing the edge emitting laser 1500 at the wafer level and/or for the purpose of reflecting optical emissions from the edge emitting laser 1500 in a substantially perpendicular direction in the edge emitting laser that is later produced from the edge emitting laser 1500 at the wafer level.

Referring to FIG. 15B, the edge emitting laser 1500 produced from the partial cross section view of the wafer depicted in FIG. 15A is shown according to an example embodiment of the present invention. As shown in FIG. 15B, the edge emitting laser 1500 includes an active region 1515 from which two optical emissions 1520A and 1520B are transmitted upon application of a sufficient current 1530. The edge emitting laser 1500 includes two reflective surfaces 1510A and 1510B for reflecting both of the optical emissions 1525A and 1525B emitted from the active region 1515 in a substantially perpendicular direction. In this manner the reflective surfaces 1510A and 1510B may allow for different packaging and setup for the edge emitting laser 1500 than that that was previously available for conventional edge emitting lasers.

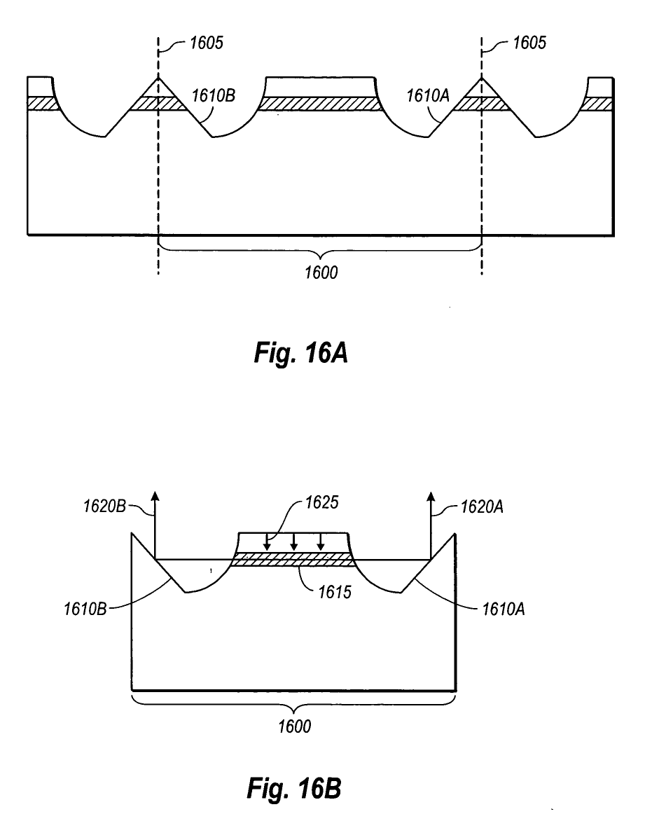

Referring to FIG. 16A a cross-sectional illustration of an edge emitting laser 1600 is illustrated while the edge emitting laser 1600 is at the wafer level. The edge emitting laser 1600 is substantially similar to that depicted in FIG. 9 at this point as shown in FIG. 16A. However, the location where cleaved facets will later be produced as shown by dotted lines 1605 has been located such that two reflective surfaces 1610A and 1610B that were produced (e.g., by a manufacturing process such as an anisotropic etching process) will be retained when the edge emitting laser 1600 is produced as a final product. This can be accomplished by cleaving or cutting the wafer at the locations indicated by dotted lines 1605 in FIG. 16A. As described above, the reflective surfaces 1610A and 1610B can be produced at the wafer level for the purpose of testing the edge emitting laser 1600 at the wafer level and/or for the purpose of reflecting an optical emission from the edge emitting laser 1600 in a substantially perpendicular direction in the final edge emitting laser product 1600.

Referring to FIG. 16B, the edge emitting laser produced from the partial cross section view of the wafer depicted in FIG. 16A is shown according to an example embodiment of the present invention. The edge emitting laser 1600 includes an active region 1615 from which two optical emissions 1620A and 1620B are transmitted from upon application of a sufficient current 1625 to the edge emitting laser 1600. The edge emitting laser 1600 includes two reflective surfaces 1610A and 1610B for reflecting both of the optical emissions 1620A and 1620B emitted from the active region 1615 in a substantially perpendicular direction from the direction in which they are emitted from the active region 1615. In this manner the reflective surfaces 1620A and 1620B can allow for different packaging and setup for the edge emitting laser 1600 than that that was previously available for conventional edge emitting lasers.

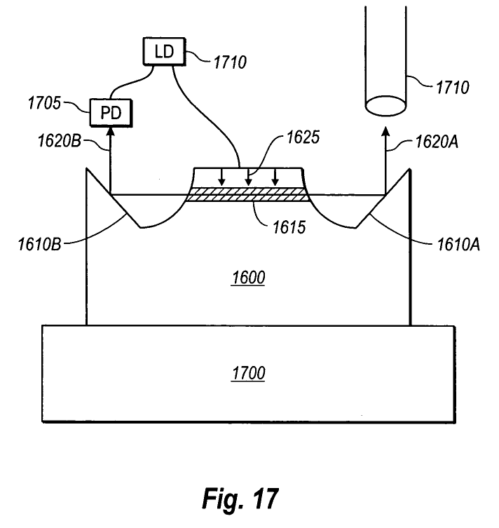

Referring to FIG. 17, an illustration depicting how the integral reflective surfaces 1610A and 1610B can change the packaging arrangement and setup of the edge emitting laser 1600. The edge emitting laser 1600 can be located upon a header 1700 or other appropriate means for supporting the edge emitting laser 1600 in a particular position and alignment. As shown, the edge emitting laser 1600 emits two optical signals 1620A and 1620B from each end of the active region 1615 upon application of a sufficient current 1625. A first optical emission 1620B is reflected from a first integral reflective surface 1610B and is received by a photodiode 1705. A second optical emission 1620A is reflected from a second integral reflective surface 1610A and is received by an optical fiber 1710. In this manner, both the laser diode 1705 and the optical fiber 1710 can be located above the edge emitting laser to receive one of the optical signals 1620A or 1620B in a direction substantially perpendicular to the direction at which the optical emissions exit the active region 615 of the edge emitting laser 1600. The photodiode 1705 can serve any purpose, for example, the photodiode 1705 can monitor the output of the edge emitting laser 1600 and provide feedback to a laser driver 1710 that provides a drive current to the edge emitting laser 1600.

The present invention may be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is claimed is:

1. A method for testing edge emitting lasers at the wafer level, the method comprising:
forming edge emitting lasers on a semiconductor wafer;
etching one or more grooves into the semiconductor wafer to form etched facets for the edge emitting lasers;
applying a current to at least one of the edge emitting lasers to produce an optical output from the at least one edge emitting laser; and
performing an evaluation of the optical output for the at least one edge emitting laser while the at least one edge emitting laser is still in the wafer form.

2. The method of claim 1, wherein the edge emitting lasers include at least one of distributed feedback laser, quantum well lasers, strained layer lasers, distributed bragg reflector lasers, and a quarter wave shifted distributed feedback laser.

3. The method of claim 1, further comprising applying at least one of an anti-reflection coating and a high reflective coating to the etched facets.

4. The method of claim 1, further comprising at least one of:
selectively marking each edge emitting laser that fails the evaluation;
refraining from performing additional manufacturing processes for each edge emitting laser that does not satisfy the evaluation, the manufacturing processes including one or more of cleaving the edge emitting lasers, polishing the edge emitting lasers, and coating portions of the edge emitting lasers;
discarding each edge emitting laser that fails the evaluation; and
selectively cleaving the ends of the edge emitting lasers based on whether the edge emitting lasers pass the evaluation.

5. The method of claim 1, further comprising reflecting the optical output in a direction toward a testing apparatus so as to be received and evaluated by the testing apparatus.

6. The method of claim 5, further comprising etching the one or more grooves so as to produce a reflective surface that reflects the optical output substantially 90 degrees.

7. The method of claim 1, wherein etching one or more grooves into the semiconductor wafer further comprises at least one of:
performing an isotropic etch; and
performing an anisotropic etch.

8. The method of claim 1, wherein one or more of the etched facets are angled to reduce reflectivity of the etched facets.

9. A semiconductor wafer comprising:
a plurality of edge emitting lasers formed on a substrate, the plurality of edge emitting layers including a top cladding layer on an active region;
one or more grooves etched into a the top cladding layer and extending through the active region of the plurality of edge emitting lasers, the one or more grooves forming one or more etched facets for the plurality of edge emitting lasers; and
wherein the one or more etched facets are configured to allow transmission of an optical signal from the active regions of the plurality of edge emitting lasers while the plurality of edge emitting lasers are still in wafer form.

10. The semiconductor wafer of claim 9, wherein the plurality of edge emitting lasers include at least one of a distributed feedback laser, a quantum well laser, a strained layer laser, and a distributed bragg reflector laser.

11. The semiconductor wafer of claim 9, wherein the one or more etched facets are etched to produce one or more reflective surfaces for reflecting the optical signal in a direction substantially perpendicular a plane of the active region.

12. The semiconductor wafer of claim 9, wherein the one or more etched facets are angled to reduce reflectivity.

13. The semiconductor wafer of claim 9, further comprising at least one of:
an antireflective coating applied to the etched facet; and
a highly reflective coating applied to the etched facet.

14. An edge emitting laser produced from the semiconductor wafer of claim 9.

15. The edge emitting laser of claim 14, wherein the edge emitting laser is manufactured in part by cleaving the edge emitting laser from the semiconductor wafer, wherein the cleaving is located back from where the etched facets are produced.

16. The edge emitting laser of claim 14, wherein the edge emitting laser includes at least one integral reflection surface created by the etched grooves.

17. The edge emitting laser of claim 16, wherein at least one integral reflection surface is configured to reflect an optical signal in a substantially 90 degree angle.

18. A method for manufacturing edge emitting lasers including testing the edge emitting lasers while the edge emitting lasers are still in wafer form, the method comprising:
providing a semiconductor wafer having edge emitting lasers grown thereon;
forming a plurality of grooves in the semiconductor wafer, wherein the plurality of grooves form facets for the edge emitting lasers;
applying a current to at least one of the edge emitting lasers such that the at least one edge emitting laser emits laser light, wherein the laser light is reflected by surfaces of the plurality of grooves toward a testing apparatus;
evaluating the laser light emitted from the at least one edge emitting laser to determine whether the at least one edge emitting laser passes an evaluation; and
selectively discarding or performing additional manufacturing steps on the at least one edge emitting laser based on a result of the evaluation.

19. The method of claim 18, wherein the plurality of grooves are formed using an etching process.

20. The method of claim 18, further comprising receiving the laser light that is reflected from a surface of the plurality of grooves for the evaluation.

21. The method of claim 18, wherein the surfaces of the plurality of grooves further comprise a reflective surface created by at least one of an anisotropic etch and an isotropic etch.

22. The method of claim 18, further comprising at least one of:
angling at least one of the facets to reduce reflectivity at the at least one facet;
angling a waveguide of at least one edge emitting laser;
applying an antireflective coating one or more of the facets; and
applying a highly reflective coating to one or more of the facets.

23. The method of claim 18, further comprising one or more of:
cleaving the semiconductor wafer to form cleaved facets that are located inward from the etched facets;
coating one or more of the cleaved facets with either an antireflective coating or a highly reflective coating;
sawing the semiconductor wafer into individual edge emitting lasers; and
polishing the individual edge emitting lasers.

24. The edge emitting laser of claim 24, further comprising at least one of an integral reflective surface and an etched facet.
